(19) United States
(12) Patent Application Publication
(10) Pub. No.: US 2010/0215071 A1
(43) Pub. Date: Aug. 26, 2010

(54) SEMICONDUCTOR LASER

(75) Inventor: Go Sakaino, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/468,958

(22) Filed: May 20, 2009

(30) Foreign Application Priority Data
Feb. 24, 2009 (JP) 2009-040132

(51) Int. Cl. H01S 5/187

(52) U.S. Cl. 372/50.11

(57) ABSTRACT

A semiconductor laser including a p-type semiconductor layer, an active layer, and an n-type semiconductor layer sequentially laminated on a p-type semiconductor substrate; and a diffraction grating in the n-type semiconductor layer along the direction of an optical waveguide. The reflectance of light on two facing laser end surfaces is asymmetric; the length L of the active layer in the optical waveguide direction is 130 μm or shorter; the diffraction grating material has a photoluminescence wavelength of 1,200 nm or longer; and κL, which is the product of the length L and the coupling coefficient κ of the diffraction grating, is at least 1.5 and smaller than 3.0.

### BACKGROUND OF THE INVENTION

1. Field of the Invention

The present invention relates to a semiconductor laser that can improve high-speed response and single-mode characteristics while securing favorable initial characteristics and long-term reliability.

2. Background Art

Semiconductor lasers for optical communications that perform direct modulation must realize high-speed response of about 10 Gbps even at high temperatures. Therefore, the optimization of the quantum well structure of the active layer, the enhancement of reflection by the coating of light-outgoing end surfaces, the reduction of parasitic capacitance, the shortening of the length L of the active layer in the optical waveguide direction, the elevation of the connection coefficient K of the diffraction grating in the semiconductor laser of the distributed feedback or distributed reflection type, or the use of a material having Al element, such as AlGaInAs for the active layer is performed.

### SUMMARY OF THE INVENTION

When high-speed response of 20 Gbps or higher is required, the length L of the active layer is shortened to 200 μm or shorter. However, if the length L is shortened, κL is also reduced, sufficient relaxation oscillation frequency cannot be obtained, and the sufficient effect of improving high-speed response by shortening cannot be obtained. Therefore, the connection coefficient κ must be extremely enlarged to, for example, about twice the conventional connection coefficient.

Methods for realizing this include a method to weaken the optical confinement of the active layer, a method to bring the distance between the diffraction grating and the active layer shorter, and a method to elevate the refractive index of the diffraction grating. However, these methods have the following problems.

Firstly, if the optical confinement of the active layer is weakened, the elevation of the threshold current and the deterioration of high-temperature characteristics due to the lowering of the gain of the semiconductor laser are caused, and the relaxation oscillation frequency that affects high-speed response is lowered.

Secondly, even if the distance between the diffraction grating and the active layer is made shorter, the lower limit of the distance is about 50 nm. The reason for this is as follows. The diffraction grating is formed after a layer having a high refractive index has been evenly formed by crystal growth, by removing the layer or making difference in the thickness at a distance determined by the oscillation wavelength. However, if the diffraction grating is made to be excessively close to the active layer, change in the connection coefficient κ becomes large when the “duty”, which is the ratio of the portions wherein the refractive index of the diffraction grating is high to the portions wherein the refractive index is low, the refractive index of the diffraction grating, the distance between the active layer and the diffraction grating is deviated from the design by the effect of the processing accuracy or the tolerance of crystal growth. If the tolerance of processing accuracy of the depth when the diffraction grating is formed becomes larger than the distance between the active layer and the diffraction grating, the active layer is also processed, and proper characteristics cannot be obtained.

Thirdly, when the refractive index of the diffraction grating is elevated, the PL wavelength determined by the composition of the diffraction grating is shifted toward the long wavelength side. Specifically, the band gap of the diffraction grating becomes smaller than the band gap of the surrounding material, such as InP. FIG. 17 is a band diagram of a semiconductor laser wherein the diffraction grating is formed in the p-type semiconductor layer; and FIG. 18 is a band diagram of a semiconductor laser wherein the diffraction grating is formed in the n-type semiconductor layer. As shown in FIG. 17, when the diffraction grating is formed in the p-type semiconductor layer, the movement of holes having large effective mass is interfered, sufficient carriers cannot be implanted into the active layer, and the light-emitting efficiency of the semiconductor laser is lowered. To solve this problem, the diffraction grating is formed in the n-type semiconductor layer as shown in FIG. 18.

FIG. 19 is a graph showing the relation between the slope effect and the PL wavelength of the diffraction grating. When the diffraction grating is formed in a p-type InP layer, the slope effect, which is the optical efficiency, is reduced as the PL wavelength of the diffraction grating is closer to the long wavelength side. On the other hand, when the diffraction grating is formed in the n-type InP layer, the slope effect is constant regardless of the PL wavelength of the diffraction grating.

FIGS. 20 and 21 are sectional views showing a conventional semiconductor laser. This semiconductor laser uses a general n-type semiconductor substrate 100, and an n-type semiconductor layer 102 and an active layer 104 are sequentially laminated thereon. A diffraction grating 106 is formed in the n-type semiconductor layer 102 to enhance the light-emitting efficiency. The p-type semiconductor layer and the like above the active layer 104 are omitted in the drawings.

In conventional semiconductor lasers, the diffraction grating 106 is formed before the active layer 104 is formed. Therefore, fine irregularity on the surface of the diffraction grating 106 causes dislocation or composition modulation in the active layer 104, and significantly affects initial characteristics and long-term reliability. Particularly when the active layer 104 is formed of a material containing Al element, such as AlGaInAs, this effect is significant.

On the other hand, a semiconductor laser wherein a diffraction grating is formed in an n-type semiconductor layer on an active layer using a p-type semiconductor substrate has also been proposed (for example, refer to Japanese Patent Application Laid-Open No. 2003-51640). In this semiconductor laser, the above-described problems are not caused. However, the κL of the semiconductor laser is larger than 3.6 and smaller than 5.6. Therefore, in a semiconductor laser of the AR/HR type wherein the reflectance of light on two facing laser end surfaces is asymmetric, there was a problem wherein κL was excessively large, and the single-mode characteristics were deteriorated.

To solve the above-described problems, it is an object of the present invention to provide a semiconductor laser that can improve high-speed response and single-mode characteristics while securing favorable initial characteristics and long-term reliability.

According to one aspect of the present invention, a semiconductor laser wherein: a p-type semiconductor layer, an active layer, and an n-type semiconductor layer are sequentially laminated on a p-type semiconductor substrate; a diffraction grating is formed in said n-type semiconductor layer along the direction of an optical waveguide; the reflectance of light on two facing laser end surfaces is asymmetric; the length L of said active layer in the optical waveguide direction is 130 μm or shorter; said diffraction grating is formed of a substance having a PL wavelength of 1,200 nm or longer; and κL, which is the product of said length L and the connection coefficient κ of said diffraction grating is 1.5 or larger and smaller than 3.0.

According to the present invention, a semiconductor laser that can improve high-speed response and single-mode characteristics while securing favorable initial characteristics and long-term reliability can be provided.

Other and further objects, features and advantages of the invention will appear more fully from the following description.

### BRIEF DESCRIPTION OF THE DRAWINGS

FIGS. 1 and 2 are sectional views showing a semiconductor laser according to the first embodiment.

FIG. 3 is a sectional view showing a modified example of the semiconductor laser according to the first embodiment.

FIGS. 4 to 12 are sectional views showing the manufacturing process of a semiconductor laser according to the first embodiment.

FIG. 13 is a graph showing the relation between the length L of the active layer and κL of the semiconductor laser for each PL wavelength of the diffraction grating.

FIG. 14 is a sectional view showing a semiconductor laser according to the second embodiment.

FIG. 15 is a sectional view showing a semiconductor laser according to the third embodiment.

FIG. 16 is a top view showing a semiconductor laser according to the fourth embodiment.

FIG. 17 is a band diagram of a semiconductor laser wherein the diffraction grating is formed in the p-type semiconductor layer.

FIG. 18 is a band diagram of a semiconductor laser wherein the diffraction grating is formed in the n-type semiconductor layer.

FIG. 19 is a graph showing the relation between the slope effect and the PL wavelength of the diffraction grating.

FIGS. 20 and 21 are sectional views showing a conventional semiconductor laser.

### DETAILED DESCRIPTION OF THE PREFERRED EMBODIMENTS

### First Embodiment

### [Structure]

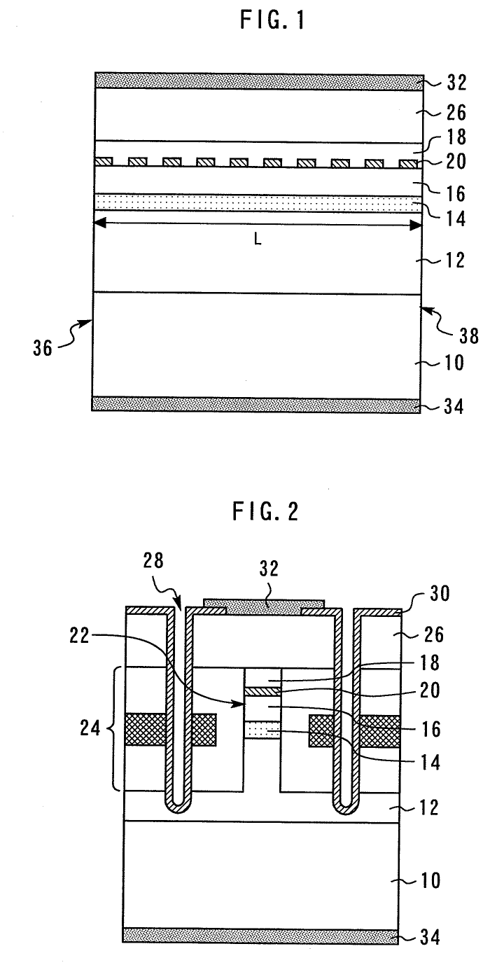

FIGS. 1 and 2 are sectional views showing a semiconductor laser according to the first embodiment. FIG. 1 is a sectional view in the optical waveguide direction; and FIG. 2 is a sectional view parallel to the end surface of the laser. The semiconductor laser is a distributed feedback type semiconductor laser.

On a p-type InP substrate 10, a p-type InP clad layer 12, an active layer 14 composed of InGaAsP, an n-type InP clad layer 16 and an n-type InP layer 18 are sequentially laminated. In the n-type InP clad layer 16 and the n-type InP layer 18, a diffraction grating 20 is formed along the optical waveguide direction. The diffraction grating 20 is formed by removing parts of an InGaAsP layer having a PL wavelength of 1,200 nm or longer at a prescribed distance determined by the oscillation wavelength.

By the p-type InP clad layer 12, the active layer 14, the n-type InP clad layer 16, and the n-type InP layer 18, a mesa 22, which is a current narrowing structure, is formed. The both sides of the mesa 22 are buried by current blocking layers 24 composed of p-type InP/n-type InP/p-type InP. The current blocking layer 24 is not limited to the above-described structure, but may be composed of an Fe-doped semi-insulating semiconductor layer or the like.

On the current blocking layer 24 and the mesa 22, an n-type InP layer 26 is formed. Penetrating the n-type InP layer 26 and the current blocking layer 24, grooves 28 are formed. In the grooves 28 and on the n-type InP layer 26, an insulating film 30 is formed. In the opening portion of the insulating film 30, an n-side electrode 32 is formed on the n-type InP layer 26. A p-side electrode 34 is formed on the back face of the p-type InP substrate 10.

An outgoing end surface 36 for extracting light and a rear end surface 38 are formed so as to face one another. To these laser end surfaces, asymmetric coating is applied so that the outgoing end surface 36 has a low reflectance and the rear end surface 38 has a high reflectance. Specifically, the light reflectance of the outgoing end surface 36 is asymmetric to the light reflectance of the rear end surface 38. The length L of the active layer 14 in the optical waveguide direction is 130 μm or shorter. The product κL of the length L and the connection coefficient κ of the diffraction grating 20 is 1.5 or longer and shorter than 3.0.

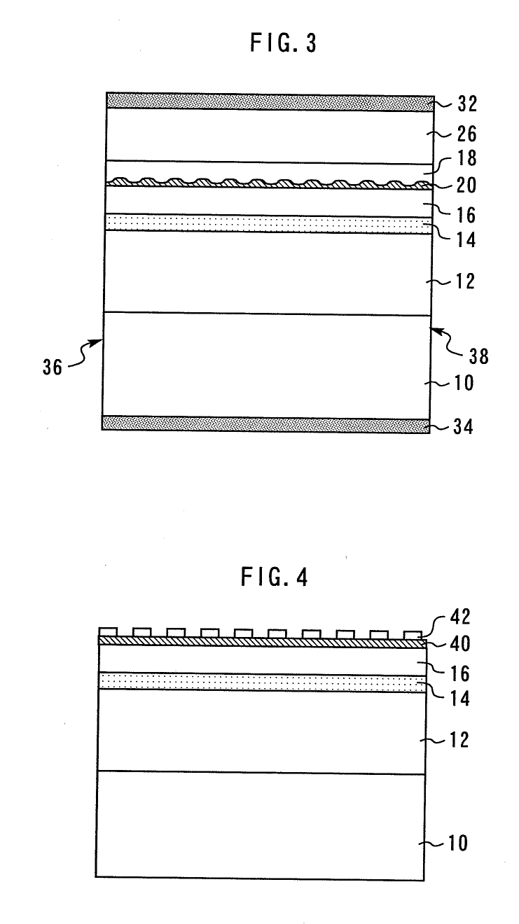

FIG. 3 is a sectional view showing a modified example of the semiconductor laser according to the first embodiment. The diffraction grating 20 may be formed by forming steps on the InGaAsP layer at a prescribed distance as shown in FIG. 3.

### [Manufacturing Process]

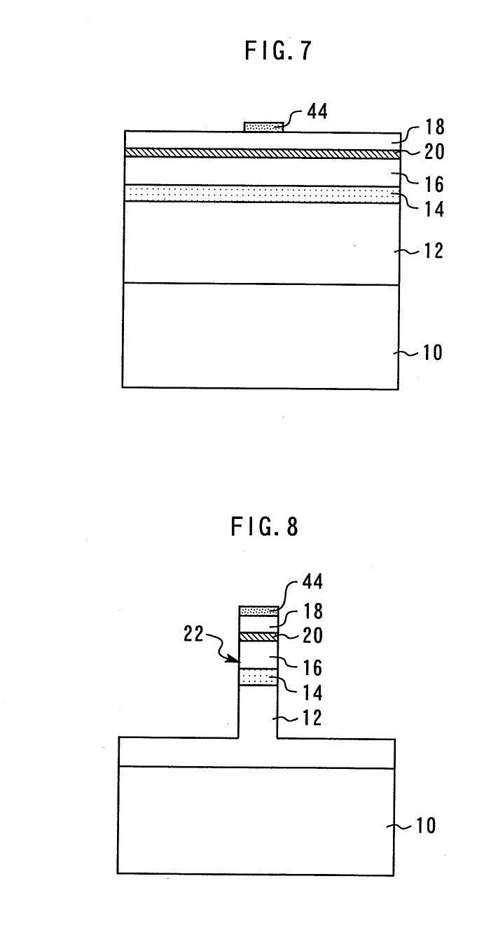

The manufacturing process of a semiconductor laser according to the first embodiment will be described referring to the drawings. FIGS. 4 to 12 are sectional views showing the manufacturing process of a semiconductor laser according to the first embodiment; FIGS. 4 to 6 being sectional view in the optical waveguide direction, and FIGS. 7 to 12 being sectional view parallel to the end surface of the laser.

Firstly, as shown in FIG. 4, on a p-type InP substrate 10, a p-type InP clad layer 12, an active layer 14 composed of InGaAsP, an n-type InP clad layer 16, and an n-type InGaAsP layer 40 are sequentially laminated. An insulating film 42 is formed on the entire surface of the n-type InGaAsP layer 40. The insulating film 42 is patterned by interference exposure or electron-beam exposure, and etching.

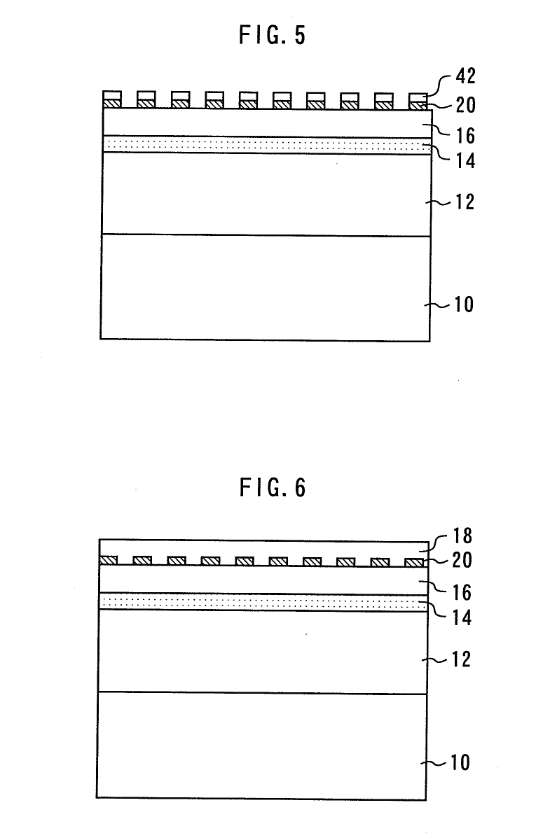

Next, as shown in FIG. 5, the n-type InGaAsP layer 40 is etched using the patterned insulating film 42 as a mask to form a diffraction grating 20. Thereafter, as shown in FIG. 6, the insulating film 42 is removed, and an n-type InP layer 18 is formed on the n-type InP clad layer 16 and the diffraction grating 20.

Next, as shown in FIG. 7, a patterned resist 44 is formed on the n-type InP layer 18. Then, as shown in FIG. 8, the p-type InP clad layer 12, the active layer 14, the n-type InP clad layer 16, and the n-type InP layer 18 are etched using the resist 44 as a mask to form a mesa 22.

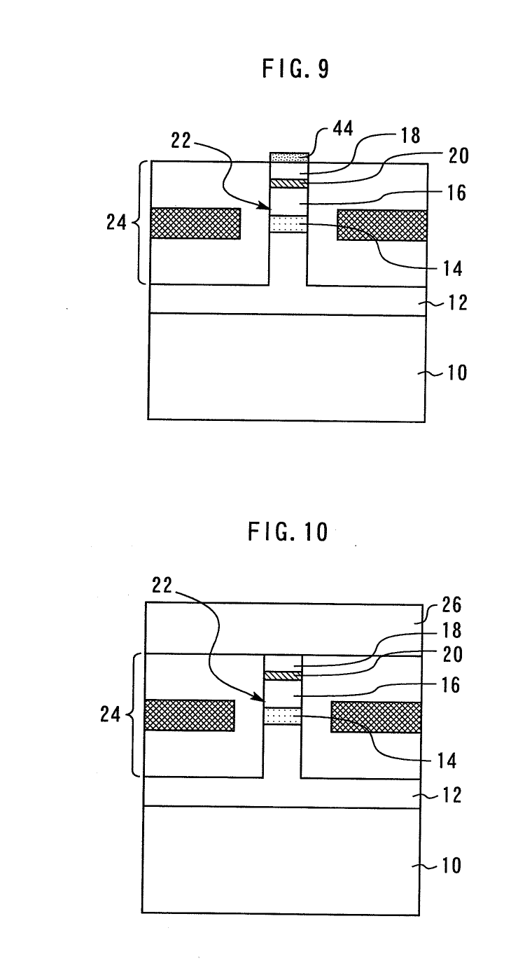

Next, as shown in FIG. 9, current blocking layers 24 are selectively grown on the both sides of the mesa 22 leaving the resist 44. Then, as shown in FIG. 10, the resist 44 is removed, and an n-type InP layer 26 is formed on the current blocking layers 24 and the mesa 22.

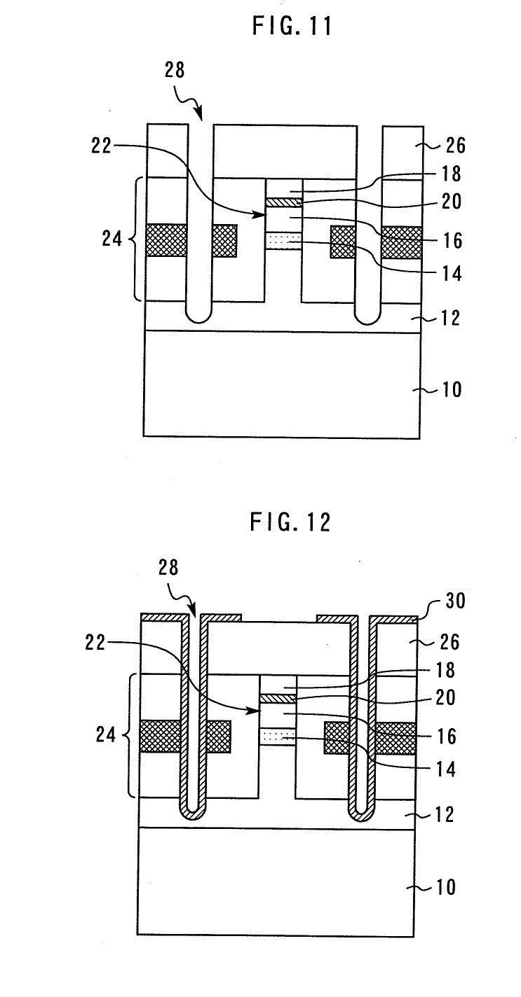

Next; as shown in FIG. 11, grooves 28 penetrating the n-type InP layer 26 and the current blocking layers 24 are formed on the outsides of the current blocking layers 24 leaving a part thereof adjacent to the active layer 14. Then, as shown in FIG. 12, insulating films 30 are formed in the grooves 28 and on the n-type InP layer 26. The insulating film 30 only above the mesa 22 is removed to form an opening. Furthermore, as shown in FIGS. 1 and 2, an n-side electrode 32 and a p-side electrode 34 are formed. Thereafter, an outgoing end surface 36 and a rear end surface 38 are formed by cleavage, and the both surfaces are coated so that the reflectance of light becomes asymmetric to one another. Then, connected semiconductor lasers are separated into individual elements, and they are mounted in a package or the like and used.

### [Effect]

In the first embodiment, the diffraction grating is formed in the n-type semiconductor layer on the active layer using the p-type semiconductor substrate. By forming the diffraction grating in the n-type semiconductor layer as described, the light-emitting efficiency of the semiconductor laser is not lowered as in the case wherein the diffraction grating is formed in the p-type semiconductor layer. In addition, since the diffraction grating is formed on the active layer, the active layer can be properly grown so as not to cause dislocation or compositional modulation, and favorable initial characteristics and long-term reliability can be secured.

When a high-speed response of 20 Gbps or higher is required, in order to obtain required modulation wavelength, a relaxation oscillation frequency equivalent to the frequency of the modulation signal (20 GHz) or higher is required. This is the same as the fact that a relaxation oscillation frequency equivalent to the frequency of the modulation signal (10 GHz) or higher is required for the 10 Gbps use. In a conventional semiconductor laser of the 10 Gbps use, when the length L of the active layer in the optical waveguide direction is 200 μm, the relaxation oscillation frequency of about 16 GHz can be obtained at a room temperature. Here, the relaxation oscillation frequency is in inverse proportion to the square root of the length L. Therefore, by determining the length L to 130 μm or shorter, the relaxation oscillation frequency of 20 GHz or higher can be obtained.

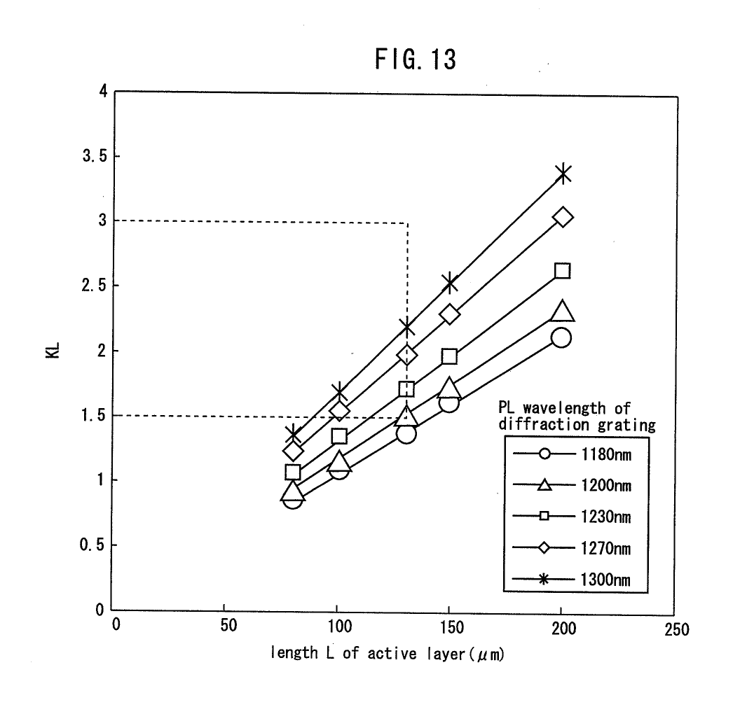

FIG. 13 is a graph showing the relation between the length L of the active layer and κL of the semiconductor laser for each PL wavelength of the diffraction grating. In the first embodiment, by forming the diffraction grating 20 with InGaAsP having a PL wavelength of 1,200 nm or longer, κL of 1.5 or larger, which is generally used, can be obtained in the semiconductor laser wherein the length L of the active layer 14 is 130 μm or shorter. Therefore, the high-speed response can be improved.

In a semiconductor laser of the AR/HR type wherein the reflectance of light on two facing laser end surfaces is asymmetric, if κL is excessively large, the single-mode characteristics are deteriorated. In the first embodiment, since κL is smaller than 3.0, the single-mode characteristics can be improved.

In the first embodiment, although the active layer 14 is formed of InGaAsP, which is used in normal optical semiconductor lasers for communications, it may also be formed of a material containing Al element, such as AlGaInAs. In this case, since the adverse effect by forming the active layer on the diffraction grating is significant, the configuration wherein the diffraction grating is formed on the active layer is particularly effective.

### Second Embodiment

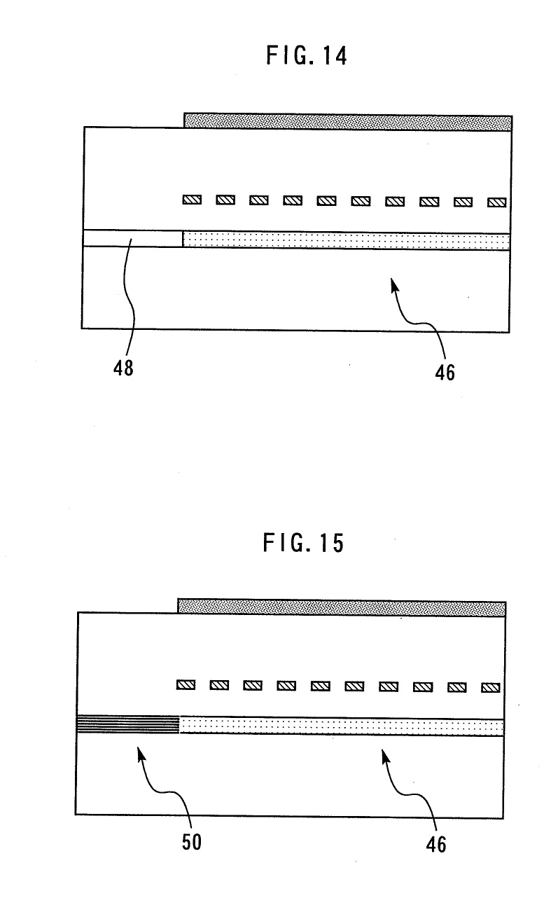

FIG. 14 is a sectional view showing a semiconductor laser according to the second embodiment. A waveguide 48 for taking out the outgoing light from the semiconductor laser 46 is integrated to the semiconductor laser 46 of the first embodiment.

### Third Embodiment

FIG. 15 is a sectional view showing a semiconductor laser according to the third embodiment. A semiconductor element 50, such as a semiconductor modulator and a semiconductor optical amplifier is integrated to the semiconductor laser 46 of the first embodiment.

### Fourth Embodiment

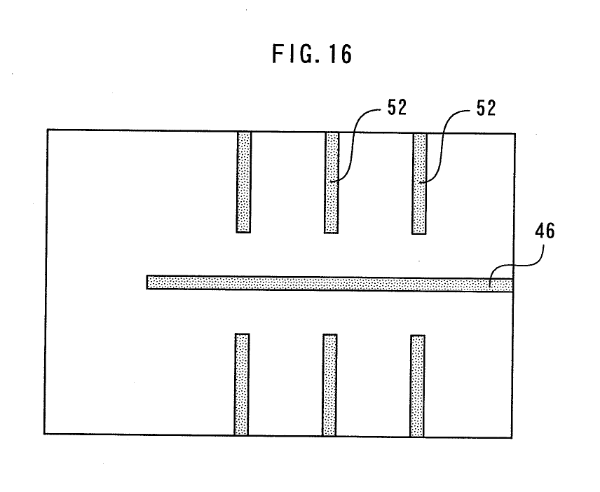

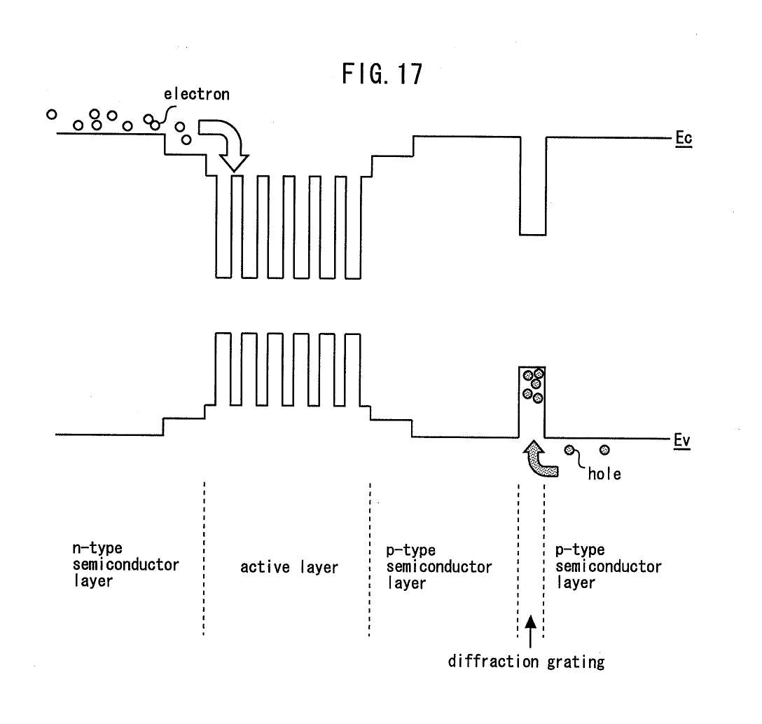

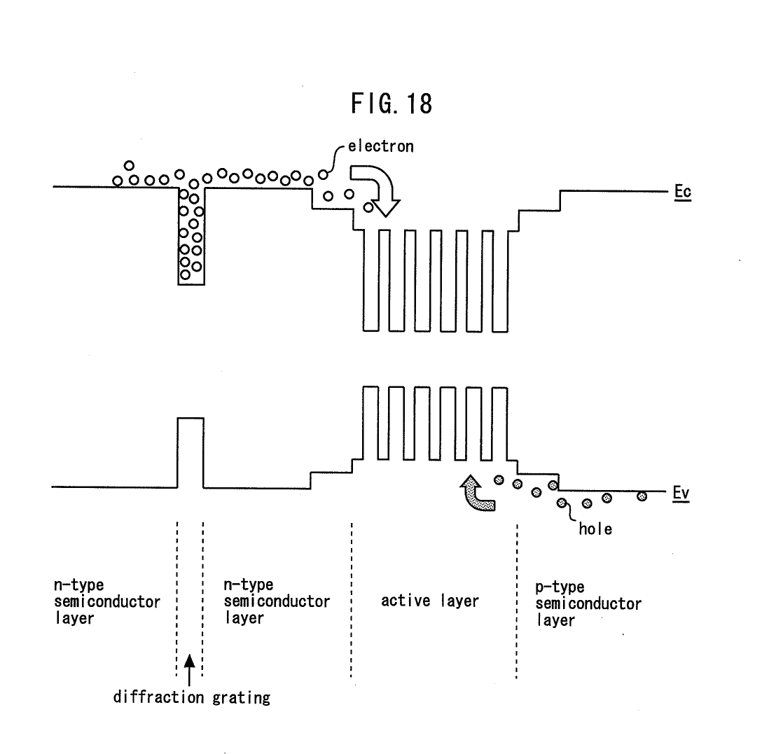

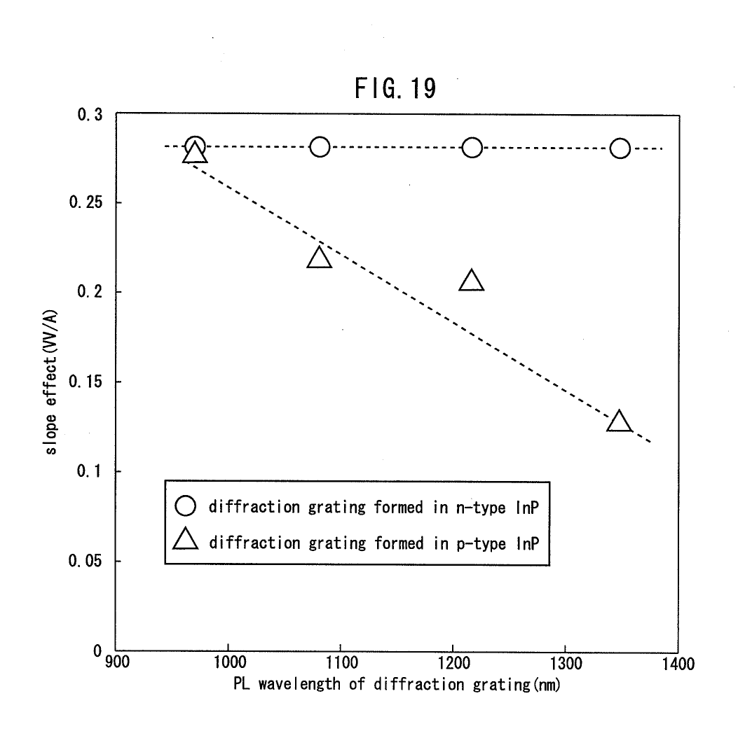

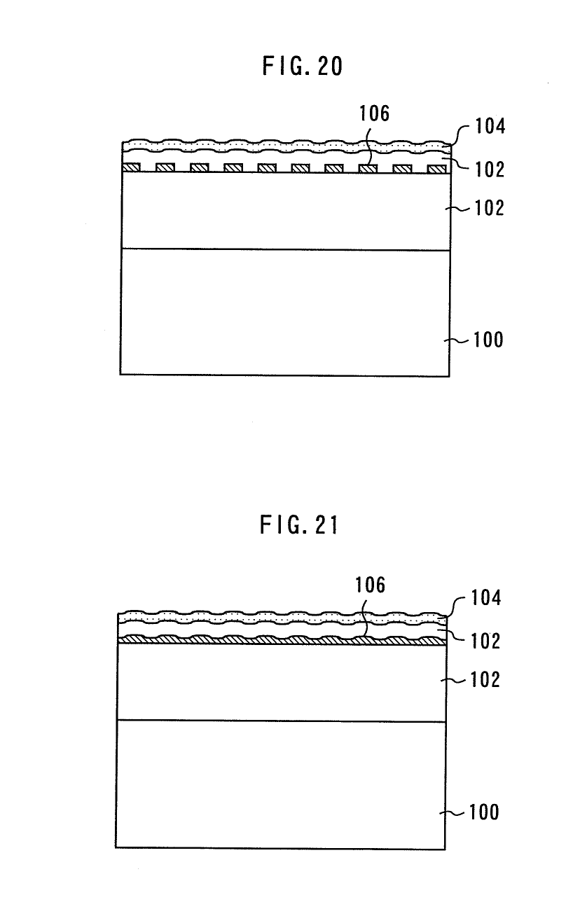

FIG. 16 is a top view showing a semiconductor laser according to the fourth embodiment. Another semiconductor laser 52 for injecting light from the side is integrated to the semiconductor laser 46 of the first embodiment.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-040132, filed on Feb. 24, 2009 including specification, claims, drawings and summary, on which the Convention priority of the present application is based, are incorporated herein by reference in its entirety.

1. A semiconductor laser comprising:
a p-type semiconductor layer, an active layer, and an n-type semiconductor layer sequentially laminated on a p-type semiconductor substrate and including two facing end surfaces defining, in an active layer, between the end surfaces, an optical waveguide of length L; and
a diffraction grating in the n-type semiconductor layer along an optical waveguide; direction, wherein
reflectance of light on the two facing laser end surfaces is asymmetrical,
the length L does not exceed 130 μm,
the n-type layer including the diffraction grating has a photoluminescence wavelength of at least 1,200 nm, and
κL, which is the product of the length L and a coupling coefficient κ of the diffraction grating, is at least 1.5 and smaller than 3.0.

2. The semiconductor laser according to claim 1, wherein the diffraction grating is in InGaAsP.

3. The semiconductor laser according to claim 1, wherein said active layer is a compound semiconductor material containing Al as a principal element.
